(19) United States
(12) Patent Application Publication
(10) Pub. No.: US 2016/0181460 A1
(43) Pub. Date: Jun. 23, 2016

(54) Avalance Photodiode

(71) Applicant: Huawei Technologies Co., Ltd., Shenzhen (CN)

(72) Inventor: Xu Pan, Shenzhen (CN)

(21) Appl. No.: 15/056,385

(22) Filed: Feb. 29, 2016

Related U.S. Application Data
(63) Continuation of application No. PCT/CN2013/082504, filed on Aug. 28, 2013.

(51) Int. Cl. H01L 31/107; H01L 31/0352; H01L 31/0312

(52) U.S. Cl. CPC H01L 31/1075; H01L 31/0312; H01L 31/035272

(57) ABSTRACT

An avalanche photodiode includes a P-type contact layer, a light absorption layer, a compositionally-graded symmetrical multiplication layer, and an N-type contact layer. The P-type contact layer is connected to the light absorption layer, the light absorption layer is connected to the compositionally-graded symmetrical multiplication layer, and the compositionally-graded symmetrical multiplication layer is connected to the N-type contact layer. The compositionally-graded symmetrical multiplication layer is configured to amplify the electrical signal, and the compositionally-graded symmetrical multiplication layer has a centrosymmetric structure and includes multiple graded layers and the multiple graded layers are used to suppress ionization of a carrier in order to reduce an excess noise factor, and the symmetrical structure of the compositionally-graded symmetrical multiplication layer effectively relaxes a large stress of a lattice mismatched system, thereby obtaining a high-quality epitaxy film, and reducing noise.

### CROSS-REFERENCE TO RELATED APPLICATIONS

This application is a continuation of International Application No. PCT/CN 2013/082504, filed on Aug. 28, 2013, which is hereby incorporated by reference in its entirety.

### TECHNICAL FIELD

The present disclosure relates to the field of electronic devices, and in particular, to an avalanche photodiode.

### BACKGROUND

With the development of communications technologies, a fiber optic communications technology becomes a main manner for information transmission because of its advantages of wide transmission frequency band, high immunity to interference, and small signal attenuation. The avalanche photodiode is an important optical-to-electrical signal conversion component in the fiber optic communications technology, and noise performance of the avalanche photodiode is critical to sensitivity of signals. Therefore, how to reduce noise of the avalanche photodiode becomes an important issue.

In the prior art, an excess noise factor is reduced by changing a material of a multiplication region of the avalanche photodiode, and a ratio K of a hole ionization rate to an electron ionization rate of the changed material of the multiplication region is lower. For example, for a silicon germanium (SiGe) avalanche photodiode, when a Si material is used in place of a Ge material as the material of the multiplication layer, the ratio K of the hole ionization rate to the electron ionization rate can be reduced, thereby reducing the excess noise factor, and achieving an objective of reducing noise.

During the implementation of the present disclosure, it is found that the prior art has at least the following problems.

In the prior art, noise of the avalanche photodiode is reduced using a method of changing the material of the multiplication region. Because the K value is an inherent property of the material, the K value of the multiplication region whose material has been changed is restricted by the material, and the excess noise factor and the noise cannot be further reduced.

### SUMMARY

### Technical Problem

To resolve an issue of further reducing an excess noise factor and noise, embodiments of the present disclosure provide an avalanche photodiode, aiming to resolve a technical issue of reducing a noise factor and noise of an inherent material.

### Technical Solution

According to a first aspect, the avalanche photodiode includes a P-type contact layer, a light absorption layer, a compositionally-graded symmetrical multiplication layer, and an N-type contact layer, where the P-type contact layer is connected to the light absorption layer, the light absorption layer is connected to the compositionally-graded symmetrical multiplication layer, and the compositionally-graded symmetrical multiplication layer is connected to the N-type contact layer, and the compositionally-graded symmetrical multiplication layer is configured to amplify the electrical signal, and the compositionally-graded symmetrical multiplication layer has a centrosymmetric structure and includes multiple graded layers.

In a first possible implementation manner of the first aspect, a material of the avalanche photodiode is a SiGe material.

With reference to the first possible implementation manner of the first aspect, in a first possible implementation manner, the avalanche photodiode further includes a charge layer, where the charge layer is configured to adjust an electric field distribution of each layer, the charge layer has a doping concentration of greater than or equal to 10¹⁷/cubic centimeter (cm³), the charge layer has a thickness range of 50 nanometer (nm) to 200 nm, and the charge layer is located between the light absorption layer and the symmetrical graded multiplication layer.

With reference to the first possible implementation manner of the first aspect, in a second possible implementation manner, the P-type contact layer has a doping concentration of greater than or equal to 10¹⁹/cm³, and the P-type contact layer has a thickness range of 100 nm to 200 nm.

With reference to the first possible implementation manner of the first aspect, in a third possible implementation manner, the light absorption layer has a thickness range of 200 nm to 2000 nm.

With reference to the first possible implementation manner of the first aspect, in a fourth possible implementation manner, the light absorption layer is a P-doped light absorption layer, and the P-doped light absorption layer has a doping concentration of greater than or equal to 10¹⁷/cm³, or the light absorption layer is an undoped light absorption layer, and the undoped light absorption layer has a doping concentration of less than or equal to 10¹⁶/cm³.

In a second possible implementation manner of the first aspect, the N-type contact layer has a doping concentration of greater than or equal to 10¹⁹/cm³, and the N-type contact layer is connected to the compositionally-graded symmetrical multiplication layer.

In a third possible implementation manner of the first aspect, a composition of the compositionally-graded symmetrical multiplication layer is a lattice mismatched material that is symmetrically distributed, and the symmetrical distribution refers to that as positions of the graded layers in the compositionally-graded symmetrical multiplication layer change, content of a first crystal material in the graded layers increases from 0 to 100%, and then decreases from 100% to 0.

In a fourth possible implementation manner of the first aspect, a band gap width of a material of two ends in the compositionally-graded symmetrical multiplication layer is less than a band gap width of the graded layer.

In a fifth possible implementation manner of the first aspect, a thickness of each graded layer in the compositionally-graded symmetrical multiplication layer is less than or equal to a reciprocal of an ionization rate of a multiplied carrier of the graded layer.

### Beneficial Effects

Beneficial effects brought by the technical solutions in the embodiments of the present disclosure are as follows.

The avalanche photodiode provided by the embodiments of the present disclosure includes a P-type contact layer, a light absorption layer, a compositionally-graded symmetrical multiplication layer, and an N-type contact layer, where the compositionally-graded symmetrical multiplication layer is configured to amplify the electrical signal, and the compositionally-graded symmetrical multiplication layer has a centrosymmetric structure and includes multiple graded layers. According to the technical solutions in the embodiments of the present disclosure, the compositionally-graded symmetrical multiplication layer is used to suppress ionization of a carrier, thereby further reducing an excess noise factor and noise by reducing the K value.

### BRIEF DESCRIPTION OF DRAWINGS

To describe the technical solutions in the embodiments of the present disclosure more clearly, the following briefly introduces the accompanying drawings required for describing the embodiments. The accompanying drawings in the following description show merely some embodiments of the present disclosure, and a person of ordinary skill in the art may still derive other drawings from these accompanying drawings without creative efforts.

FIG. 1 is a schematic structural diagram of an avalanche photodiode according to a first embodiment of the present disclosure;

FIG. 2 is a schematic structural diagram of an avalanche photodiode according to a second embodiment of the present disclosure; and

FIG. 3 is a schematic structural diagram of a compositionally-graded symmetrical multiplication layer according to a third embodiment of the present disclosure.

### DESCRIPTION OF EMBODIMENTS

To make the objectives, technical solutions, and advantages of the present disclosure clearer, the following further describes the embodiments of the present disclosure in detail with reference to the accompanying drawings.

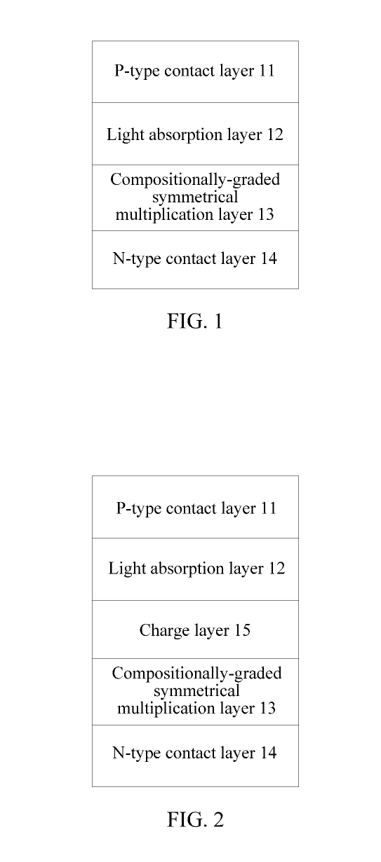

FIG. 1 is a schematic structural diagram of an avalanche photodiode according to a first embodiment of the present disclosure. Referring to FIG. 1, the avalanche photodiode includes a P-type contact layer 11, a light absorption layer 12, a compositionally-graded symmetrical multiplication layer 13, and an N-type contact layer 14.

The P-type contact layer 11 is connected to the light absorption layer 12, the light absorption layer 12 is connected to the compositionally-graded symmetrical multiplication layer 13, and the compositionally-graded symmetrical multiplication layer 13 is connected to the N-type contact layer 14.

The compositionally-graded symmetrical multiplication layer 13 is configured to amplify the electrical signal, and the compositionally-graded symmetrical multiplication layer 13 has a centrosymmetric structure and includes multiple graded layers.

The P-type contact layer 11 is configured to form a P-side ohm contact in a P—N junction.

The P-type contact layer 11 has a doping concentration of greater than or equal to 10¹⁹/cm³, and the P-type contact layer 11 has a thickness range of 100 nm to 200 nm.

Further, the P-type contact layer 11 is formed by doping monocrystalline silicon with a group III element such as boron, aluminum, gallium, or indium to replace positions of silicon atoms in the lattice, where silicon and the group III element are bonded by a covalent bond to generate an excess of holes. Doping with more group III elements indicates that more holes are generated in the P-type contact layer 11.

When an external voltage is applied to two ends of the avalanche photodiode, one of the ends is connected to the P-type contact layer 11, and conducts electricity through the P-type contact layer 11.

The light absorption layer 12 is configured to absorb an optical signal and convert the optical signal into an electrical signal. The light absorption layer 12 is connected to the P-type contact layer 11.

The light absorption layer 12 has a thickness range of 200 nm to 2000 nm.

After receiving an optical signal, the light absorption layer 12 absorbs the optical signal, and generates an electron-hole pair. The electron-hole pair moves under action of an electric field to form an electrical signal, thereby completing conversion of an optical signal to an electrical signal.

Content of a crystalline material in the compositionally-graded symmetrical multiplication layer 13 is symmetrically distributed. The symmetrical distribution refers to that as positions of the graded layers in the compositionally-graded symmetrical multiplication layer 13 differ, the content of the crystal material in the graded layers increases from 0 to 100%, and then decreases from 100% to 0.

The compositionally-graded symmetrical multiplication layer 13 generates a large quantity of electron-hole pairs using an avalanche multiplication effect, and amplify the electrical signal that is generated by the light absorption layer 12.

The avalanche multiplication effect refers to that after a reverse bias is applied to the two ends of the avalanche photodiode, an electron or a hole gains energy under action of an electric field and is accelerated. Higher energy indicates a higher speed. During movement, the carrier collides with an electron on a covalent bond, intrinsic excitation occurs, and an electron-hole pair is generated. The process is repeated. A large quantity of electron-hole pairs can be generated instantaneously.

The compositionally-graded symmetrical multiplication layer 13 includes multiple graded layers. Silicon content of the graded layers is different, and therefore band gap widths of the graded layers are different, and a heterostructure that is generated reduces an excess noise factor.

The band gap width refers to a conducting capability of a material. A smaller band gap width indicates a stronger conducting capability. A larger band gap width indicates a weaker conducting capability. For example, for a semiconductor material having a relatively small band gap width, when temperature rises, an electron may be excited, such that the semiconductor material is electrically conductive. For an insulator material having a very large band gap width, the insulator material is a poor conductor even at a relatively high temperature. A band gap is an energy region whose density of states is zero in an energy band structure, and is usually used to represent an energy range that is between valence and conduction bands and whose density of states is zero.

Noise performance of the avalanche photodiode is determined by the excess noise factor. A calculation formula of the excess noise factor is shown as follows.

F_{A}=KM+(1−K)(2−M⁻¹)

where M is a multiplication factor, and K is a ratio of a hole ionization rate β to an electron ionization rate α, that is, β/α. When the K value approaches zero, F_{A} approaches 2-M⁻¹, and reaches a minimum. When a carrier moves from a wide band gap material to a narrow band gap material, a decrease ΔE_{c} in an electron ionization threshold (ΔEₜₕ) is greater than a decrease ΔEᵥ in a hole ionization threshold (ΔEₜₕ), and an ionization rate has an exponential relationship with an ionization threshold. Therefore, the K value decreases accordingly, and the excess noise factor of the avalanche photodiode that has multiple graded layers is relatively small.

The N-type contact layer 14 is configured to form an N-side ohm contact in the P—N junction. The N-type contact layer 14 has a doping concentration of greater than or equal to 10¹⁹/cm³. The N-type contact layer 14 is connected to the compositionally-graded symmetrical multiplication layer 13.

The N-type contact layer 14 is formed by doping monocrystalline silicon with a group V element such as phosphorus, arsenic, or antimony to replace positions of silicon atoms in the lattice, where silicon and the group V element are bonded by a covalent bond to generate an excess of electrons. Doping with more group V elements indicates that more electrons are generated in the N-type contact layer 14.

When an external voltage is applied to two ends of the avalanche photodiode, one of the ends is connected to the N-type contact layer 14, and conducts electricity through the N-type contact layer 14.

The avalanche photodiode provided by this embodiment of the present disclosure includes a P-type contact layer, a light absorption layer, a compositionally-graded symmetrical multiplication layer, and an N-type contact layer, where the compositionally-graded symmetrical multiplication layer is configured to amplify the electrical signal, and the compositionally-graded symmetrical multiplication layer has a centrosymmetric structure and includes multiple graded layers. In the technical solutions provided by this embodiment of the present disclosure, the compositionally-graded symmetrical multiplication layer is used to suppress ionization of a carrier, thereby further reducing an excess noise factor and noise by reducing the K value.

Optionally, a material of the avalanche photodiode is a SiGe material.

Silicon has a lattice constant of 0.543 nm, and germanium has a lattice constant of 0.565 nm. Therefore, there is a lattice mismatch of up to 4% between silicon and germanium. When silicon is grown on a germanium material, a silicon thin film experiences a tensile stress. The silicon thin film has a critical thickness, and if the critical thickness is exceeded, defects of the silicon thin film such as cracking are caused, which affects quality of the thin film. To alleviate the problem of low thin film quality that is caused by the lattice mismatch, a symmetrical compositional multiplication layer is used, the abrupt change of 4% in the lattice constant that is from 0.543 nm of silicon to 0.565 nm of germanium as content of silicon in the graded layers changes becomes a slow change because of introduction of the graded layers, and the graded layers effectively relax the tensile stress. There is still a critical thickness for the slow change of the lattice mismatch, and to counteract the tensile stress, graded layers that are mirrored are used, such that the whole graded structure is centrosymmetric, and the tensile stresses of the slow change “counteract” each other. At the top and bottom of the compositionally-graded symmetrical multiplication layer, content of silicon is 0, and content of germanium is 100%. The symmetrical graded structure effectively relaxes the stress that is caused by the lattice mismatch, thereby obtaining a high-quality epitaxial thin film, and achieving relatively good noise performance.

Optionally, the avalanche photodiode further includes a charge layer 15.

The charge layer 15 is configured to adjust an electric field distribution of each layer, the charge layer 15 has a doping concentration of greater than or equal to 10¹⁷/cm³, the charge layer has a thickness range of 50 nm to 200 nm, and the charge layer is located between the light absorption layer 12 and the symmetrical graded multiplication layer 13.

FIG. 2 is a schematic structural diagram of an avalanche photodiode according to a second embodiment of the present disclosure. Referring to FIG. 2, during a reverse bias, the charge layer 15 properly adjusts an electrical field distribution of each layer, such that the avalanche photodiode works in an optimal state.

It should be noted that the charge layer 15 may serve as a part of the absorption layer 12, may serve as a part of the symmetrical graded multiplication layer 13, or may exist as an independent layer.

The avalanche photodiode provided by this embodiment of the present disclosure includes a P-type contact layer, a light absorption layer, a compositionally-graded symmetrical multiplication layer, and an N-type contact layer, where the compositionally-graded symmetrical multiplication layer is configured to amplify the electrical signal, and the compositionally-graded symmetrical multiplication layer has a centrosymmetric structure and includes multiple graded layers. In the technical solutions provided by this embodiment of the present disclosure, the compositionally-graded symmetrical multiplication layer is used to suppress ionization of a carrier, thereby further reducing an excess noise factor and noise by reducing the K value. Further, the charge layer is used to optimize the electrical field distribution of the avalanche photodiode, thereby reducing noise.

Optionally, the light absorption layer 12 is a P-doped light absorption layer, and the P-doped light absorption layer has a doping concentration of greater than or equal to 10¹⁷/cm³, or the light absorption layer 12 is an undoped light absorption layer, and the undoped light absorption layer has a doping concentration of less than or equal to 10¹⁶/cm³.

When the light absorption layer 12 is the P-doped light absorption layer, the group III element doped in silicon has a doping concentration of 10¹⁶/cm³. At this concentration, when there is an optical signal, excitation of an electron-hole pair is achieved, and an electrical signal is formed.

When the light absorption layer 12 is the undoped light absorption layer, that is, the light absorption layer is not doped with any other material, the light absorption layer has a doping concentration of less than or equal to 10¹⁶/cm³, where the doping concentration is formed by carriers of the light absorption layer, and conversion from an optical signal to an electrical signal can be achieved.

A composition of the compositionally-graded symmetrical multiplication layer is a lattice mismatched material that is symmetrically distributed, and the symmetrical distribution refers to that as positions of the graded layers in the compositionally-graded symmetrical multiplication layer change, content of a first crystal material in the graded layers increases from 0 to 100%, and then decreases from 100% to 0.

The first crystalline material refers to a material with a relatively large band gap width in the compositionally-graded symmetrical multiplication layer. For example, in a SiGe material, a band gap width of Ge is greater than a band gap width of Si, and therefore, the first crystalline material is Si.

As the positions of the graded layers in the compositionally-graded symmetrical multiplication layer change, the content of the first crystalline material in the compositionally-graded symmetrical multiplication layer increases from 0 to 100%, and then decreases from 100% to 0. The whole graded structure is centrosymmetric. The tensile stresses of the slow change “counteract” each other. The symmetrical graded structure effectively relaxes the stress caused by the lattice mismatch, thereby obtaining a high-quality epitaxial thin film, and reducing noise of the avalanche photodiode.

Optionally, a band gap width of a material of two ends in the compositionally-graded symmetrical multiplication layer is less than a band gap width of the graded layer.

It can be known from the above that a larger band gap width of a material indicates a lower conductivity, and a smaller band gap width of a material indicates a higher conductivity. Transition of the band gap widths of the graded layers from small to large and then from large to small is achieved by selecting a material whose band gap width is less than the band gap widths of the graded layers as the material of the two ends of the compositionally-graded symmetrical multiplication layer. In a silicon germanium material, the material of the two ends in the compositionally-graded symmetrical multiplication layer is germanium. In a III-V material, the material of the two ends in the compositionally-graded symmetrical multiplication layer is the material whose band gap width is smaller.

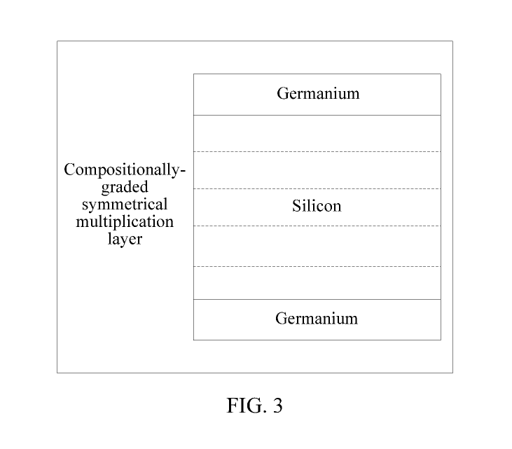

FIG. 3 is a schematic structural diagram of a compositionally-graded symmetrical multiplication layer according to a third embodiment of the present disclosure. Referring to FIG. 3, a material of the compositionally-graded symmetrical multiplication layer includes silicon and germanium, and content of silicon and germanium is symmetrically distributed in the compositionally-graded symmetrical multiplication layer. A material of two ends of the compositionally-graded symmetrical multiplication layer is germanium, and a material of a middle layer is silicon. Content of silicon in the graded layers from the top down is from 0 to 100%, and then from 100% to 0. Content of germanium in the graded layers from the top down is from 0 to 100%, and then from 100% to 0. Content of silicon and germanium in the compositionally-graded symmetrical multiplication layer may be represented by a chemical formula Si,Ge₁₋ₓ, where x has a value range of 0 to 1.

Optionally, a thickness of each graded layer in the compositionally-graded symmetrical multiplication layer is less than or equal to a reciprocal of an ionization rate of a multiplied carrier of the graded layer.

The ionization rate is a quantity of electron-hole pairs that are generated when a carrier passes by a unit distance under action of a strong electrical field. The ionization rate is correlated to the electrical field and a band gap width. The ionization rate exponentially increases as the strength of the electrical field increases, and exponentially decreases as the band gap width increases. For example, when the ionization rate of the multiplied carrier of the graded layer is α, the thickness of the graded layer is less than or equal to 1/α.

The thickness of each graded layer in the compositionally-graded symmetrical multiplication layer is limited within a range, which helps suppress ionization of a carrier, thereby reducing impact of a noise factor.

The avalanche photodiode provided by this embodiment of the present disclosure includes a P-type contact layer, a light absorption layer, a compositionally-graded symmetrical multiplication layer, and an N-type contact layer, where the compositionally-graded symmetrical multiplication layer is configured to amplify the electrical signal, and the compositionally-graded symmetrical multiplication layer has a centrosymmetric structure and includes multiple graded layers. In the technical solutions provided by this embodiment of the present disclosure, the compositionally-graded symmetrical multiplication layer is used to suppress ionization of a carrier, thereby further reducing an excess noise factor and noise by reducing the K value. Further, the charge layer is used to optimize the electrical field distribution of the avalanche photodiode, thereby reducing noise.

The foregoing descriptions are merely exemplary embodiments of the present disclosure, but are not intended to limit the present disclosure. Any modification, equivalent replacement, and improvement made without departing from the spirit and principle of the present disclosure shall fall within the protection scope of the present disclosure.

What is claimed is:

1. An avalanche photodiode, comprising:
a P-type contact layer;
a light absorption layer;
a compositionally-graded symmetrical multiplication layer; and
an N-type contact layer,
wherein the P-type contact layer is connected to the light absorption layer,
wherein the light absorption layer is connected to the compositionally-graded symmetrical multiplication layer,
wherein the compositionally-graded symmetrical multiplication layer is connected to the N-type contact layer,
wherein the compositionally-graded symmetrical multiplication layer is configured to amplify an electrical signal, and
wherein the compositionally-graded symmetrical multiplication layer has a centrosymmetric structure and comprises multiple graded layers.

2. The avalanche photodiode according to claim 1, wherein a material of the avalanche photodiode is a silicon germanium (SiGe) material.

3. The avalanche photodiode according to claim 2, further comprising a charge layer, wherein the charge layer is configured to adjust an electric field distribution of each layer, wherein the charge layer has a doping concentration of greater than or equal to 10¹⁷/cubic centimeter (cm³), wherein the charge layer has a thickness range of 50 nanometer (nm) to 200 nm, and wherein the charge layer is located between the light absorption layer and the compositionally-graded symmetrical multiplication layer.

4. The avalanche photodiode according to claim 2, wherein the P-type contact layer has a doping concentration of greater than or equal to 10¹⁹/cubic centimeter (cm³), and a thickness range of 100 nanometer (nm) to 200 nm.

5. The avalanche photodiode according to claim 2, wherein the light absorption layer has a thickness range of 200 nanometer (nm) to 2000 nm.

6. The avalanche photodiode according to claim 2, wherein the light absorption layer is a P-doped light absorption layer, wherein the P-doped light absorption layer has a doping concentration of greater than or equal to 10¹⁷/cubic centimeter (cm³), or wherein the light absorption layer is an undoped light absorption layer, and wherein the undoped light absorption layer has the doping concentration of less than or equal to 10¹⁶/cm³.

7. The avalanche photodiode according to claim 1, wherein the N-type contact layer has a doping concentration of greater than or equal to 10¹⁹/cubic centimeter (cm³), and wherein the N-type contact layer is connected to the compositionally-graded symmetrical multiplication layer.

8. The avalanche photodiode according to claim 1, wherein a composition of the compositionally-graded symmetrical multiplication layer is a lattice mismatched material that is symmetrically distributed, and wherein the symmetrical distribution refers to that as positions of the graded layers in the compositionally-graded symmetrical multiplication layer change, content of a first crystal material in the graded layers increases from 0 to 100%, and then decreases from 100% to 0.

9. The avalanche photodiode according to claim 1, wherein a band gap width of a material of two ends in the compositionally-graded symmetrical multiplication layer is less than a band gap width of the graded layer.

10. The avalanche photodiode according to claim 1, wherein a thickness of each graded layer in the compositionally-graded symmetrical multiplication layer is less than or equal to a reciprocal of an ionization rate of a multiplied carrier of the graded layer.
